(19) United States
(12) Patent Application Publication
(10) Pub. No.: US 2012/0066563 A1
(43) Pub. Date: Mar. 15, 2012

(54) ERROR CORRECTION DECODER, MEMORY CONTROLLER AND RECEIVER

(76) Inventors: Haruka OBATA, Yokohama-shi (JP); Hironori Uchikawa, Fujisawa-shi (JP)

(21) Appl. No.: 13/043,918

(22) Filed: Mar. 9, 2011

(30) Foreign Application Priority Data
Sep. 9, 2010 (JP) 2010-202095

(51) Int. Cl. H03M 13/05

(52) U.S. Cl. 714/752; 714/E11.032

(57) ABSTRACT

According to an embodiment, an error correction decoder carries out iterative decoding for data coded using an irregular LDPC code. The decoder includes a likelihood control unit. The likelihood control unit is configured to carry out weighting using first extrinsic value weights when a first condition including a condition that a code word cannot be obtained even when number of times the iterative decoding has been carried out is greater than a first iterative times, in order to increase absolute value of a extrinsic value from a check node not satisfying a parity check to a variable node, wherein the first extrinsic value weights are equal to each other or become larger in descending order of column weights of the variable nodes, and a maximum of the first extrinsic value weights is not equal to a minimum of the first extrinsic value weights.

### CROSS-REFERENCE TO RELATED APPLICATIONS

This application is based upon and claims the benefit of priority from Japanese Patent Application No. 2010-202095, filed Sep. 9, 2010; the entire contents of which are incorporated herein by reference.

### FIELD

Embodiments described herein relate generally to error correction using an irregular low-density parity check (LDPC) code.

### BACKGROUND

When transmitting or storing data, an error correction code is added to the data. The data to which the error correction code is added is decoded by an error correction decoder incorporated in a receiver or a memory controller.

If a few bit errors are included in received data or read data, the data can be accurately reconstituted by correcting the bit errors using the error correction code.

As an error correction code, an LDPC code is known. LDPC codes excel at correcting errors. Regarding LDPC codes, a phenomenon called “error floor” is known. When error floor is observed, a decoding error rate almost does not reduce in a region in which a bit error rate before decoding is below a certain level.

### BRIEF DESCRIPTION OF THE DRAWINGS

FIG. 1 is a block diagram showing an example of an error correction decoder according to the first embodiment.

FIG. 2 is an illustration of an LDPC parity check matrix.

FIG. 3 is a graph of the LDPC parity check matrix of FIG. 2 using a Tanner graph.

FIG. 4 is a graph showing a result of a parity check using the LDPC parity check matrix of FIG. 2.

FIG. 5 is a flowchart showing an example of an operation of the error correction decoder of FIG. 1.

FIG. 6 is a flowchart showing another example of an operation of the error correction decoder of FIG. 1.

FIG. 7 is a flowchart showing another example of an operation of the error correction decoder of FIG. 1.

FIG. 8 is a block diagram showing a storage apparatus according to the second embodiment.

FIG. 9 is a block diagram showing a receiver according to the third embodiment.

### DETAILED DESCRIPTION

In general, according to one embodiment, an error correction decoder carries out iterative decoding for data coded using an irregular LDPC code. The decoder includes a row processing unit, a parity check unit and a likelihood control unit. The row processing unit is configured to generate each extrinsic value from each check node to each variable node. The parity check unit is configured to generate a temporary estimated word based on the extrinsic values, to perform parity checks on the temporary estimated word, and to determine the temporary estimated word as a code word when all check nodes satisfy the parity check. The likelihood control unit is configured to carry out weighting using first extrinsic value weights when a first condition including a condition that the code word cannot be obtained even when number of times the iterative decoding has been carried out is greater than a first iterative times, in order to increase absolute value of the extrinsic value from the check node not satisfying the parity check to the variable node, wherein the first extrinsic value weights are equal to each other or become larger in descending order of column weights of the variable nodes, and a maximum of the first extrinsic value weights is not equal to a minimum of the first extrinsic value weights.

In the following, each embodiment will be explained in reference to the figures.

### First Embodiment

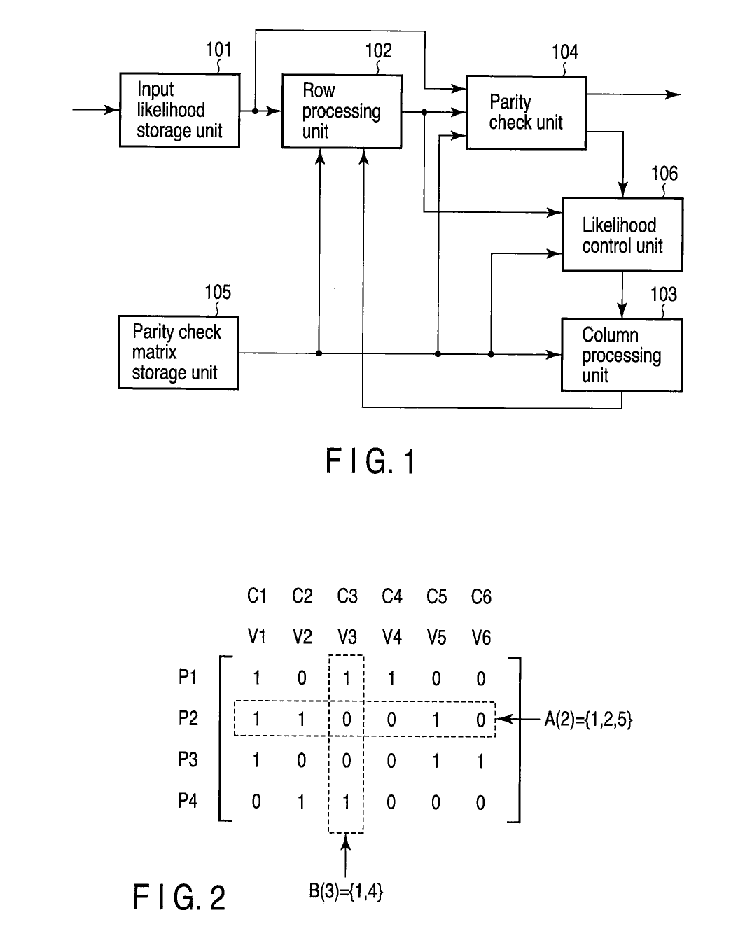

An error correction decoder according to a first embodiment includes, as shown in FIG. 1, an input likelihood storage unit 101, a row processing unit 102, a column processing unit 103, a parity check unit 104, a parity check matrix storage unit 105, and a likelihood control unit 106. Basically, the error correction decoder carries out iterative decoding based on so-called message passing decode algorithm (Sum-Product algorithm or Min-Sum algorithm decoding methods).

A likelihood of code data Fn acquired by a signal processing unit (not shown) in the previous stage is input to the input likelihood storage unit 101. The input likelihood storage unit 101 retains the input likelihood Fn until the decoding of code data is completed. The code data is an LDPC code defined by an irregular LDPC parity check matrix H (hereinafter, sometimes referred to as “parity check matrix H”) stored in the parity check matrix storage unit 105. In other words, the code data is so-called systematic code and consists of data bits and parity bits.

As an example, assuming code data consisting of two data bits C1 and C2 and four parity bits C3, . . . , C6, the likelihood storage unit 101 stores input likelihoods F1, . . . , F6 which respectively correspond to bits C1, . . . , C6. These input likelihoods F1, . . . , F6 are read by the row processing unit 102 and the parity check unit 104, as needed.

Herein, as expressed by equation (1) below, a likelihood is the natural logarithm value of the ratio of the probability P (x=0) of a data bit being 0 to the probability P (x=1) of the data bit being 1. In the description hereinafter, an apriori likelihood means the likelihood of an apriori probability.

$$ln \frac{P ( x = 0 )}{P ( x = 1 )} \qquad ( 1 )$$

The parity check matrix storage unit 105 stores information of the parity check matrix H with M rows and N columns in advance. The same parity check matrix H is shared by a decoder side and an encoder side. The parity check matrix H is read by the row processing unit 102, the column processing unit 103, the parity check unit 104 or the likelihood control unit 106, as needed.

FIG. 2 shows an example of the parity check matrix H, when M=4, N=6. The code length of the code data defined by the parity check matrix H with 4 rows and 6 columns is 6 bits, and the parity length of the code data is 4 bits. The number of “1” included in the mth row of the parity check matrix H is called a row weight of the mth row (m is an integer wherein 1≦m≦4). The number of “1” included in the nth column of the parity check matrix H is called a column weight of the nth column (n is an integer wherein 1≦n≦6). In irregular LDPC codes, a row weight and a column weight of a parity check matrix H are non-uniform.

In the explanation hereinafter, a set of column indices indicating column positions of “1” on the mth row will be referred to as A(m), a set of row indices indicating row positions of “1” in the nth column will be referred to as B(n). For example, A(2)={1, 2, 5}, B(3)={1, 4} in FIG. 2. Since a total number of “1” included in an LDPC code parity check matrix H is very small (in other words, the density of “1” is low) relative to the size of the matrix, the information of the parity check matrix H can be expressed with information on positions of “1” in the matrix, thereby saving the size of the data for the parity check matrix H. In other words, the size of the circuit in the parity check matrix storage unit 105 can be reduced.

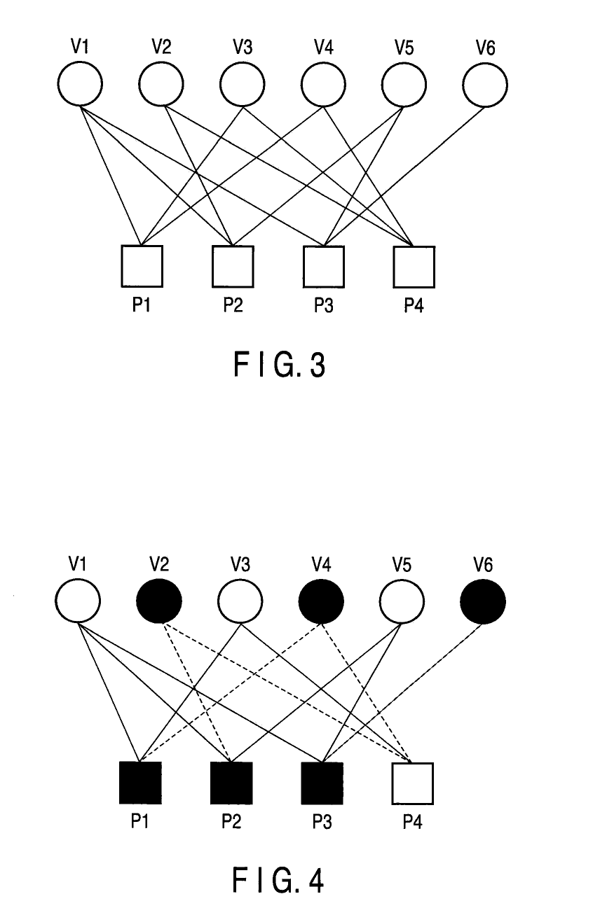

As shown in FIG. 3, the parity check matrix H of FIG. 2 can be represented in another way using a Tanner graph. A Tanner graph consists of two types of node groups: a group of variable nodes (V1, . . . , V6 in FIG. 3) and a group of check nodes (P1, . . . , P4 in FIG. 3). If the element in the mth row and the nth column is “1”, an edge connects the check node Pm to the variable node Vn.

The row processing unit 102 generates an extrinsic value αₘₙ using input likelihoods F1, . . . , F6 obtained from the input likelihood storage unit 101, the information of the parity check matrix H from the parity check matrix storage unit 105 and apriori likelihoods βₘₙ from the column processing unit 103. More specifically, the row processing unit 102 generates extrinsic value αₘₙ by the following equation (2). The row processing unit 102 inputs the generated extrinsic value αₘₙ to the parity check unit 104 and the likelihood control unit 106.

$${α}_{mn} = ( {\prod }_{{n}^{′} ∈ A ( m ) \backslash n}^{ } sign ( {Fn}^{′} + {β}_{{mn}^{′}} ) ) f ( {\prod }_{{n}^{′} ∈ A ( m ) \backslash n}^{ } f ( \vert {Fn}^{′} + {β}_{{mn}^{′}} \vert ) ) \qquad ( 2 )$$

It should be noted that every apriori likelihood βₘₙ at the first decoding is set to zero, and after the first decoding, a newest apriori likelihood βₘₙ which is fed back from the column processing unit 103 is set. The function sign(x) and the function f(x) in equation (2) are expressed by the following equation (3) and equation (4):

$$\begin{matrix}sign ( x ) = \{ \begin{matrix}1 & ( x \geq 0 ) \\ - 1 & ( x < 0 )\end{matrix} & ( 3 ) \\ f ( x ) = ln \frac{exp ( x ) + 1}{exp ( x ) - 1} & ( 4 )\end{matrix}$$

The parity check unit 104 generates a temporary estimated word based on the information of the parity check matrix H from the parity check matrix storage unit 104, extrinsic value αₘₙ from the row processing unit 102 and the input likelihood Fn from the input likelihood storage unit 101. More specifically, the parity check unit 104 generates the nth element of the temporary estimated word by the following equation (5).

$${\hat{c}}_{n} = \{ \begin{matrix}0 , & if sign ( Fn + {\sum }_{{m}^{′} ∈ B ( n )}^{ } {α}_{{m}^{′} n} ) = 1 \\ 1 , & if sign ( Fn + {\sum }_{{m}^{′} ∈ B ( n )}^{ } {α}_{{m}^{′} n} ) = - 1\end{matrix} \qquad ( 5 )$$

Then, the parity check unit 104 checks whether the generated temporary estimated word is a code word defined by the parity check matrix H or not. More specifically, the parity check unit 104 calculates a parity check vector U by the following equation (6).

U=ĉH^{T} (6)

Each element in the parity check vector U indicates whether a corresponding check node satisfies the parity check or not (whether the parity of the corresponding check node is correct or not). If the mth element in the parity check vector U is “0,” the mth check node Pm satisfies the parity check. If the mth element in the parity check vector U is “1,” the mth check node Pm does not satisfy the parity check. The total number of “1” included in the parity check vector U is equal to the total number of check nodes UCN that do not satisfy the parity check.

In the explanation hereinafter, a set of check nodes not satisfying the parity check will be referred to as UC(P), and a set of check nodes satisfying the parity check and connected (by edges) to the variable nodes that are connected (by edges) to the check nodes not satisfying the parity check will be referred to as SD(P). UCN is equal to the total number of elements included in a set UC(P).

For example, as shown in FIG. 4, if bit errors occur in variable nodes V2, V4 and V6, the parity check vector U=[1110] is obtained as a result of the parity check. In this case, UCN=3, UC(P)={P1, P2, P3}, SD(P)={P4}. In FIG. 4, the black circles represent variable nodes V2, V4 and V6 in which bit errors occur; the broken lines represent the edges connecting those variable nodes V2, V4 ad V6 to arbitrarily check nodes; and the black squares represent the check nodes that do not satisfy the parity check.

When a parity check vector U is zero vector, it means all check nodes satisfy the parity check. If the parity check vector U becomes a zero vector, the parity check unit 104 outputs a temporary estimated word as a code word. If the parity check vector U is not a zero vector, as will be described later, extrinsic value αₘₙ is updated up to a first maximum Lmax, and the parity check based on the updated extrinsic value αₘₙ is iterated. If the parity check vector U is not a zero vector and L, the number of times the iterative decoding has been carried out, is not greater than Lmax, the parity check unit 104 notifies the likelihood control unit 104 of information of the set UC(P) and information of the set SD(P). The number of times L the iterative decoding has been carried out is counted by, for example, the row processing unit 102.

When a first condition is satisfied, the likelihood control unit 106 carries out weighting on extrinsic value αₘₙ from the row processing unit 102, and it inputs the weighted extrinsic value αₘₙ to the column processing unit 103. If the first condition is not satisfied, the likelihood control unit 106 inputs extrinsic value αₘₙ without changing it from the row processing unit 102 to the column processing unit 103. The first condition is either one of or a combination of the second condition that the number of times L the iterative decoding has been carried out is greater than a first iterative times Lin, and the third condition that the UCN is less than or equal to a first maximum UCNmax.

The column processing unit 103 calculates apriori likelihood βₘₙ using the information of the parity check matrix H from the parity check matrix storage unit 105 and extrinsic value αₘₙ (which may be weighted as needed) from the likelihood control unit 106. More specifically, the column processing unit 103 calculates apriori likelihood βₘₙ by the following equation (7). The column processing unit 103 feeds the calculated apriori likelihood βₘₙ back to the row processing unit 102.

$${β}_{mn} = {\sum }_{{m}^{′} ∈ B ( n ) \backslash m}^{ } {α}_{{m}^{′} n} \qquad ( 7 )$$

In equation (7), the extrinsic value αₘₙ is input from the likelihood control unit 106, and it may or may not be weighed.

The error correction decoder shown in FIG. 1 achieves error correction decoding by usual iterative decoding without weighting extrinsic value αₘₙ at the likelihood control unit 106. However, the error correction decoder shown in FIG. 1 attempts to reduce the error floor (i.e., improvement of ability to correct errors) by means of weighting extrinsic value αₘₙ at the likelihood control unit 106 as will be described below, when a code word cannot be obtained after carrying out the regular iterative decoding, for example, Lin times.

Below, the technical significance of weighting extrinsic value αₘₙ and the specific processes of weighting extrinsic value αₘₙ will be explained.

Suppose if a result of the parity check as illustrated in FIG. 4 is obtained as a result of carrying out the regular iterative decoding Lin times, for example. Since a bit error occurs in each of variable nodes V2, V4 and V6, check nodes P1, P2 and P3 do not satisfy the parity check; on the other hand, check node P4 satisfies the parity check. It should be noted that check node P4 only temporarily satisfies the parity check because of bit errors occurring in variable nodes V2 and V4. For example, if either one of the bit errors in variable nodes V2 and V4 is corrected, check node P4 will no longer satisfy the parity check. Consequently, regarding the example shown in FIG. 4, it can be considered that extrinsic value α₄₂ that is sent from check node P4 satisfying the parity check to variable node V2 is actually an inappropriate value, but extrinsic value α₂₂ that is sent from check node P2 not satisfying the parity check to variable node V2 is actually an appropriate value. Accordingly, the possibility that the bit error at variable node V2 will be corrected is increased by weighting the inappropriate extrinsic value α₄₂ so as to decrease an effect thereof (e.g., an absolute value), or by weighting the appropriate extrinsic value α₂₂ so as to increase an effect thereof. However, the error correction decoder shown in FIG. 1 is incapable of determining whether a check node that satisfies the parity check (e.g., check node P4 in FIG. 4) truly satisfies the parity check, or it merely satisfies the parity check temporarily because of an occurrence of bit errors in an even number of variable nodes.

The error correction decoder of FIG. 1 carries out weighting on extrinsic value αₘₙ from each of the check nodes not satisfying the parity check (i.e., each of the elements in the set UC(P)) to each variable node in a manner such that effects of the extrinsic values are increased. On the other hand, the error correction decoder of FIG. 1 carries out weighting on extrinsic value αₘₙ from the check nodes (i.e., each of the elements in the set SD(P)) satisfying the parity check that are connected to the variable nodes connected to the check nodes not satisfying the parity check to the variable nodes connected to the check nodes not satisfying the parity check in a manner such that the effects of the extrinsic values are decreased. It can be assumed that the set SD(P) includes elements that only temporarily satisfy the parity check because of an occurrence of bit errors in the even number of variable nodes. The error correction decoder shown in FIG. 1 may perform either or both of the weighting extrinsic value αₘₙ from each element in the set UC(P) to each variable node and the weighting extrinsic value αₘₙ from each element in the set SD(P) to each variable αₘₙ node connected to a check node not satisfying the parity check. In the explanation hereinafter, the error correction decoder shown in FIG. 1 performs both of the weightings.

Also, as described above, irregular LDPC codes are expected to be used in the present embodiment. The irregular LDPC codes are non-uniform with respect to a column weight and a row weight. Generally, a bit error occurs more often in a variable node with a small column weight. Accordingly, in the present embodiment, a tendency of bit error occurrence according to a column weight is considered when weighting extrinsic value αₘₙ. More specifically, in the present embodiment, an individual extrinsic value weight is applied to extrinsic value αₘₙ for every column weight w_{c}(n). For example, a larger extrinsic value weight (>1) is used as the multiplier for extrinsic value α₃₁ to be sent from check node P3 to a variable node V1 with a small column weight (i.e., with a lower reliability), and a smaller extrinsic value weight (<1) is used as the multiplier for extrinsic value α₃₆ to be sent from the same check node P3 to variable node V6 with a larger column weight (i.e., with a greater reliability).

More specifically, the likelihood control unit 106 can carry out weighting extrinsic value αₘₙ from each element in the set UC(P) to each variable node, according to the following equation (8):

$${α}_{mn} = \{ \begin{matrix}{W}_{u 1} {α}_{mn} if {w}_{c} ( n ) = 1 \\ {W}_{u 2} {α}_{mn} if {w}_{c} ( n ) = 2 \\ {W}_{u 3} {α}_{mn} if {w}_{c} ( n ) = 3\end{matrix} \qquad ( 8 )$$

It should be noted that extrinsic value weights, Wᵤ₁, Wᵤ₂ and Wᵤ₃ in equation (8) satisfy the following condition (9):

1<Wᵤ₃≦Wᵤ₂≦Wᵤ₁ AND Wᵤ₃<Wᵤ₁ (9)

It should be noted that, although equation (8) and condition (9) exemplify a case in which there are three types of column weight w_{c}(n), the equation and condition can be generalized into a case in which there are two types or four or more types of column weight w_{c}(n). Regardless of the type of column weight w_{c}(n), extrinsic value weight wᵤᵢ corresponding to each column weight w_{c}(n) will be equal to each other, or become greater in accordance with descending order of column weight i. In other words, extrinsic value weight wᵤᵢ does not become smaller in a descending order of column weight i. Also, regardless of the type of column weight w_{c}(n), maximum value Wᵤᵢ_{_{—}}ₘᵢₙ of the extrinsic value weight is greater than minimum value Wᵤᵢ_{_{—}}ₘₐₓ of the extrinsic value weight (in other words, maximum value Wᵤᵢ_{_{—}}ₘᵢₙ of the extrinsic value weight is not equal to minimum value Wᵤᵢ_{_{—}}ₘₐₓ of the extrinsic value weight.) Herein, i_max indicates a maximum of column weight and i_min indicates a minimum of column weight. By such a way of weighting using extrinsic value weight Wᵤᵢ, an absolute value of extrinsic value αₘₙ from each element in the set UC(P) to each variable node can be appropriately increased in accordance with column weight i.

Also, the likelihood control unit 106 can carry out weighting extrinsic value αₘₙ from each element of the set SD(P) to the variable node connected to the check node which does not satisfy the parity check, by the following equation (10).

$${α}_{mn} = \{ \begin{matrix}{W}_{s 1} {α}_{mn} if {w}_{c} ( n ) = 1 \\ {W}_{s 2} {α}_{mn} if {w}_{c} ( n ) = 2 \\ {W}_{s 3} {α}_{mn} if {w}_{c} ( n ) = 3\end{matrix} \qquad ( 10 )$$

Extrinsic values Wₛ₁, Wₛ₂ and Wₛ₃ in equation (10) satisfy the following condition (11):

1>Wₛ₃≧Wₛ₂≧Wₛ₁ AND Wₛ₃>Wₛ₁ (11)

It should be noted that, although equation (10) and condition (11) exemplify a case in which there are three types of column weight w_{c}(n), the equation and condition can be generalized into a case in which there are two types or four or more types of column weight w_{c}(n). Regardless of the type of column weight w_{c}(n), extrinsic value weight wₛᵢ corresponding to each column weight w_{c}(n) will be equal to each other, or become smaller in accordance with descending order of column weight i. In other words, extrinsic value weight wₛᵢ does not become greater in accordance with descending order of column weight i. Also, regardless of the type of column weight w_{c}(n), maximum value Wₛᵢ_{_{—}}ₘₐₓ of the extrinsic value weight is greater than minimum value Wₛᵢ_{_{—}}ₘᵢₙ of the extrinsic value weight (in other words, maximum value Wₛᵢ_{_{—}}ₘₐₓ of the extrinsic value weight is not equal to minimum value Wₛᵢ_{_{—}}ₘᵢₙ of the extrinsic value weight.) By such a way of weighting using extrinsic value weight Wₛᵢ, an absolute value of extrinsic value αₘₙ from each element in the set SD(P) to each variable node connected to the check nodes not satisfying the parity check can be appropriately reduced in accordance with column weight i.

Also, the likelihood control unit 106 can carry out weighting of extrinsic value αₘₙ from each element of the set UC(P) to each variable node by the following equation (12) instead of equation 8.

$${α}_{mn} = \{ \begin{matrix}sign ( {α}_{mn} ) ( \vert {α}_{mn} \vert + \vert {V}_{u 1} \vert ) if {w}_{c} ( n ) = 1 \\ sign ( {α}_{mn} ) ( \vert {α}_{mn} \vert + \vert {V}_{u 2} \vert ) if {w}_{c} ( n ) = 2 \\ sign ( {α}_{mn} ) ( \vert {α}_{mn} \vert + \vert {V}_{u 3} \vert ) if {w}_{c} ( n ) = 3\end{matrix} \qquad ( 12 )$$

Extrinsic value weights |Vᵤ₁|, |Vᵤ₂| and |Vᵤ₃| in Equation (12) satisfy the following condition (13):

|Vᵤ₃|≦|Vᵤ₂|≦|Vᵤ₁| AND |Vᵤ₃|<|Vᵤ₁| (13)

It should be noted that, although equation (12) and condition (13) exemplify a case in which there are three types of column weight w_{c}(n), the equation and condition can be generalized into a case in which there are two types or four or more types of column weight w_{c}(n). Regardless of the type of column weight w_{c}(n), extrinsic value weight |Vᵤᵢ| corresponding to each column weight w_{c}(n) will be equal to each other, or become greater in accordance with descending order of column weight i. In other words, extrinsic value weight |Vᵤᵢ| does not become smaller in accordance with descending order of column weight i. Also, regardless of the type of column weight w_{c}(n), maximum value |Vᵤᵢ_{_{—}}ₘᵢₙ| of the extrinsic value weight is greater than minimum value |Vᵤᵢ_{_{—}}ₘₐₓ| of the extrinsic value weight (in other words, maximum value |Vᵤᵢ_{_{—}}ₘᵢₙ| of the extrinsic value weight is not equal to minimum value |Vᵤᵢ_{_{—}}ₘₐₓ| of the extrinsic value weight.) By such a way of weighting using extrinsic value weight |Vᵤᵢ|, an absolute value of extrinsic value αₘₙ from each element in the set UC(P) to each variable node can be appropriately increased in accordance with column weight i.

Further, the likelihood control unit 106 may perform a combination of weighting by multiplication by weight coefficients greater than 1 indicated by equation (8) and weighting by addition of absolute values indicated by equation (12).

Also, the likelihood control unit 106 can carry out weighting extrinsic value αₘₙ from each element in the set SD(P) to the variable node connected to the check node not satisfying the parity check, by the following equation (14) instead of equation (10).

$${α}_{mn} = \{ \begin{matrix}sign ( {α}_{mn} ) ( \vert {α}_{mn} \vert - \vert {V}_{s 1} \vert ) if {w}_{c} ( n ) = 1 \\ sign ( {α}_{mn} ) ( \vert {α}_{mn} \vert - \vert {V}_{s 2} \vert ) if {w}_{c} ( n ) = 2 \\ sign ( {α}_{mn} ) ( \vert {α}_{mn} \vert - \vert {V}_{s 3} \vert ) if {w}_{c} ( n ) = 3\end{matrix} \qquad ( 14 )$$

Extrinsic value weights (−|Vₛ₁|), (−|IVₛ₂|) and (−|Vₛ₃|) in equation (14) satisfy the following condition (15):

−|Vₛ₃≧−|Vₛ₂≧−|Vₛ₁| AND −|Vₛ₃|>−|Vₛ₁| (15)

It should be noted that, although equation (14) and condition (15) exemplify a case in which there are three types of column weight w_{c}(n), the equation and condition can be generalized into a case in which there are two types or four or more types of column weight w_{c}(n). Regardless of the type of column weight w_{c}(n), extrinsic value weight (−|Vₛ₁|) corresponding to each column weight w_{c}(n) will be equal to each other, or become smaller in accordance with descending order of column weight i. In other words, extrinsic value weight (−|Vₛᵢ|) does not become greater in accordance with a descending order of column weight i. Also, regardless of the type of column weight w_{c}(n), maximum value (−|Vₛᵢ_{_{—}}ₘₐₓ|) of the extrinsic value weight is greater than minimum value (−|Vₛᵢ_{_{—}}ₘᵢₙ|) of the extrinsic value weight (in other words, maximum value (−|Vₛᵢ_{_{—}}ₘₐₓ|) of the extrinsic value weight is not equal to minimum value (−|Vₛᵢ_{_{—}}ₘᵢₙ|) of the extrinsic value weight.) By such a way of weighting using extrinsic value weight (−|Vₛᵢ|), an absolute value of extrinsic value αₘₙ from each element in the set SD(P) to each variable node connected to the check nodes not satisfying the parity check can be appropriately decreased in accordance with column weight i.

Further, the likelihood control unit 106 may perform a combination of weighting by multiplication by weight coefficients smaller than 1 indicated by equation (10) and weighting by subtraction of absolute values (addition of sign-changed absolute values) indicated by equation (14).

As described above, considering that a bit error occurs more often in a variable node with a smaller column weight, an extrinsic value αₘₙ can be weighted by setting an individual extrinsic value weight (such as Wᵤᵢ, Wₛᵢ, |Vᵤᵢ|, (−|Vₛᵢ|), etc.) so that the ability to correct errors can be effectively improved in a situation, for example shown in FIG. 4.

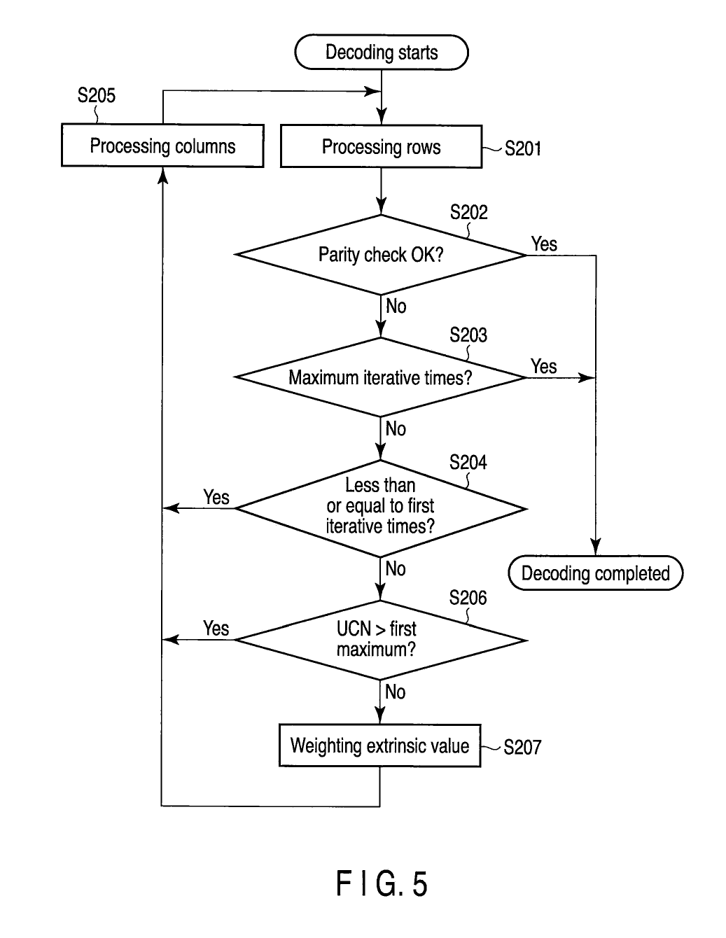

In the following, an example of the operation of the error correction decoder of FIG. 1 will be explained using FIG. 5. The process of FIG. 5 begins upon an input of likelihood Fn acquired by the signal processing unit in the previous stage to the input likelihood storage unit 101, and then the process proceeds to step S201. The process ends when a code word (a result of error correction decoding) is obtained (decoding succeeded) or when a code word cannot be obtained even when the number of times L the iterative decoding has been carried out is greater than the maximum iterative times Lmax (decoding failed), and likelihood Fn related to what to be processed next is input to the input storage unit 101.

In step S201, the row processing unit 102, as aforementioned, generates extrinsic value αₘₙ using the input likelihood Fn from the input likelihood storage unit 101, the information of the parity check matrix H from the parity check matrix storage unit 105 and newest) apriori likelihood βₘₙ from the column processing unit 103. The row processing unit 102 may count how many times the iterative decoding has been carried out (L times) every time the process at step S201 is carried out. Next, as aforementioned, the parity check unit 104 generates a temporary estimated word based on the information of parity check matrix H from the parity check matrix storage unit 105 and extrinsic value αₘₙ from the row processing unit 102, and determines whether the generated temporary estimated word is a code word that is defined by the parity check matrix H or not (step S202). If the temporary estimated word is determined as a code word, the process ends (decoding succeeded), and if not, the process proceeds to step S203.

In step S203, the likelihood control unit 106 determines whether the number of times L the iterative decoding has been carried out is greater than the first maximum Lmax or not. If greater, the process ends (decoding failed), and if not, the process proceeds to step S204. In step S204, the likelihood control unit 106 determines whether the number of times L the iterative decoding has been carried out is less than or equal to the first iterative times Lin or not. Here, Lin<Lmax. If less or equal, the process proceeds step S205, and if not, the process proceeds to step S206. In step S206, the likelihood control unit 106 determines whether UCN the total number of check nodes that do not satisfy the parity check is greater than UCNmax the first maximum. If greater, the process proceeds to step S205, and if not, the process proceeds to step S207.

In step S207, the likelihood control unit 106 carries out weighting extrinsic value αₘₙ as aforementioned, and the process proceeds to step S205. In step S205, the column processing unit 103 calculates apriori likelihood βₘₙ using information of the parity check matrix H from the parity check matrix storage unit 105 and extrinsic value αₘₙ from the likelihood control unit 106 (if the process proceeds to step S205 via step S207, extrinsic value αₘₙ has been weighted), and the process returns to step S201.

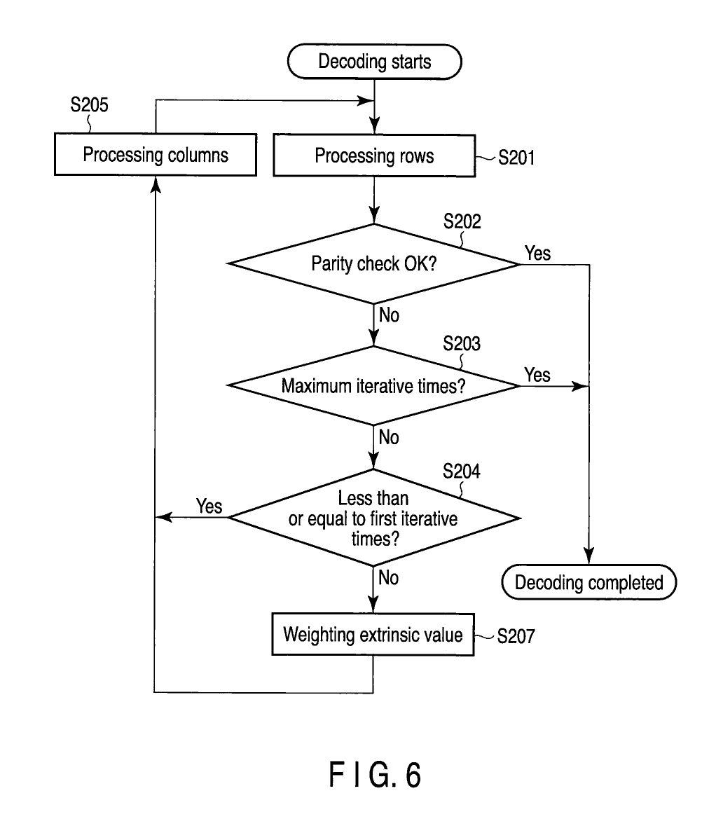

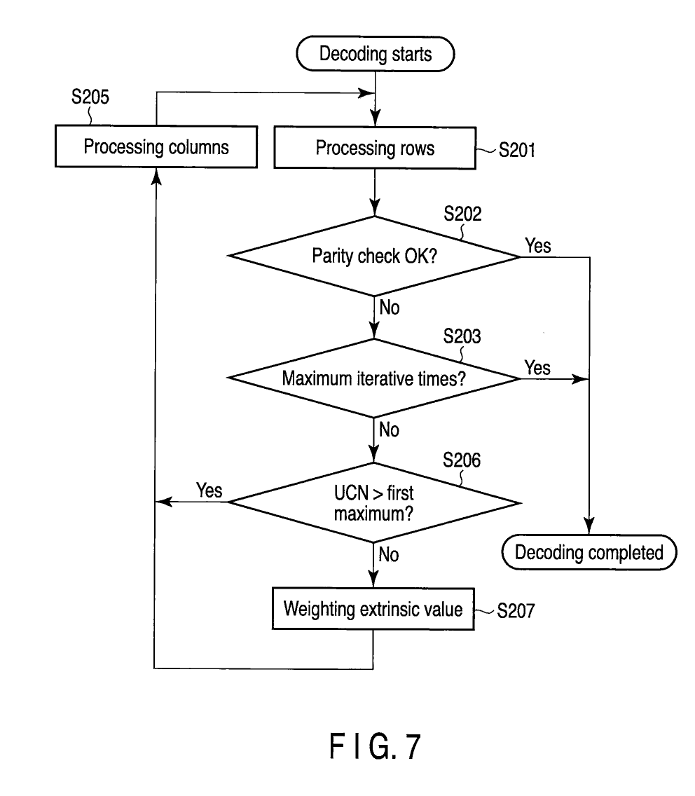

Note that the example of FIG. 5 adopts the combination of the second condition that the number of times L the iterative decoding has been carried out is greater than the first iterative times Lin (step S204) and the third condition that UCN the total number of check nodes not satisfying the parity check is less than UCNmax the first maximum (step S206). However, it is also possible to make a branch to step S207 (the likelihood control unit 106 carries out weighting) when either one of the second condition and the third condition is satisfied. The variation using only the second condition is shown in FIG. 6 and the variation using only the third condition is shown in FIG. 7. If at least either one of the second condition and the third condition is used, it is possible to narrow down to a situation in which improvement of the ability of error correction achieved by weighting extrinsic value αₘₙ can be expected (e.g., the situation shown in FIG. 4). For example, improvement in the error correction ability can be expected when weighting extrinsic value αₘₙ is carried out after carrying out the regular iterative decoding sufficient times without weighting extrinsic value αₘₙ. Improvement in the error correction ability can also be expected when weighting extrinsic values are carried out after UCN the total number of check nodes not satisfying the parity check becomes sufficiently small.

As explained above, the error correction decoder according to the first embodiment sets an individual extrinsic value weight for each column weight in order to weight extrinsic values when a first condition is satisfied (for example, when iterative decoding has been carried out sufficient times). Thus, according to the error correction decoder according to the present embodiment, the ability of error correction can be effectively improved using the tendency that bit errors occur more often in a variable node with a small column weight, when a code word cannot be obtained in spite of iterative decoding sufficient times.

### Second Embodiment

The storage apparatus according to a second embodiment is an application of the error correction decoder according to the above first embodiment. The storage apparatus is typically a memory card which includes a nonvolatile memory such as a flash memory and a memory controller to control the nonvolatile memory.

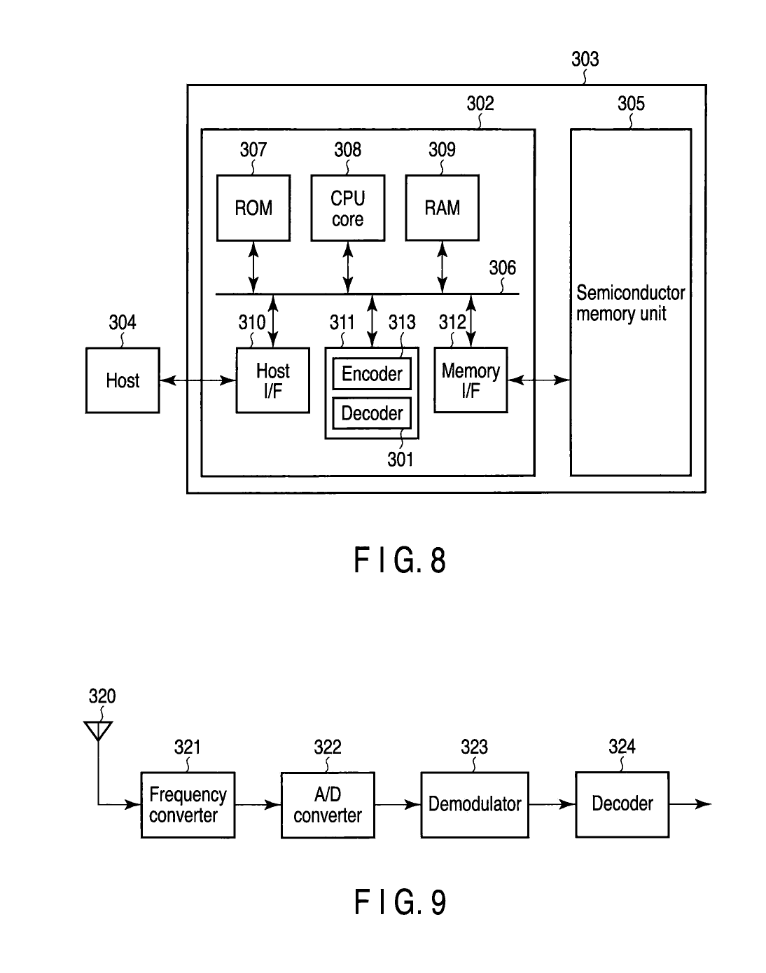

A memory card 303 of FIG. 8 includes a semiconductor memory unit 305 which is a nonvolatile memory and a memory controller 302 which controls the semiconductor memory unit 305. The memory card 303 removably connects to a host 304 (e.g., a personal computer, a digital camera, a cellphone, etc.) to transmit and receive data with the host 304. For example, the host 304 can read data from and write data on the memory card 303.

The memory controller 302 includes a read-only memory (ROM) 307, a central processing unit (CPU) core 308, a random access memory (RAM) 309, a host interface (I/F) 310, an error correction unit 311 and a memory interface 312. Each element of the memory controller 302 is connected to each other via a bus 306.

The CPU core 308 transmits and receives data with the host 304 through the host interface 310 and with the semiconductor memory unit 305 through the memory interface 312. In other words, the CPU core 308 can function as a reading unit to receive data from the semiconductor memory unit 305 or as a writing unit to transmit data on the semiconductor memory unit 305. Firmware executed by the CPU core 308 realizes address management of the semiconductor unit 306 including restrictions on the number of rewritable times. Further, the firmware realizes the control of whole memory card 303 in accordance with commands input from the host 304.

The ROM 307 stores a control program for the memory card 303, etc. The RAM 309 stores an address conversion table which is necessary for address management, information on abnormal circuits, and so on.

The error correction unit 311 includes a decoder 301 and an encoder 313. The error correction decoder according to the first embodiment is incorporated into to the decoder 301. The decoder 301 performs error correction decoding on data read from the semiconductor memory unit 305. On the other hand, the encoder 313 adds an error correction code to data to be written on the semiconductor memory 305.

As explained in the above, in the storage apparatus according to the second embodiment, the error correction decoder according to the aforementioned first embodiment is incorporated into the memory controller. Thus, according to the storage apparatus according to the present embodiment, an excellent ability of error correction on the read data can be achieved.

### Third Embodiment

The receiver according to the third embodiment is an application of the error correction decoder according to the aforementioned first embodiment. The receiver according to the present embodiment includes, as shown in FIG. 9, an antenna 320, a frequency converter 321, an analog-to-digital converter 322, a demodulator 323 and a decoder 324. The receiver of FIG. 9 receives encoded and modulated signals and reconstructs received data by demodulating and decoding. Typically, the receiver of FIG. 9 may be a wireless receiver (which supports cellular communication and a wireless local area network [LAN]) or a broadcast receiver. The receiver may also include a low-noise amplifier (LNA) or a filter (not shown in FIG. 9).

The antenna 320 receives high-frequency radio signals. The frequency converter 321 downconverts the received signals from the antenna 320 to intermediate-frequency signals. The analog-to-digital converter 322 digitizes the domain of the intermediate frequency signals from the frequency converter 321. The demodulator 323 demodulates the digital signals from the analog-to-digital converter 322 in accordance with a demodulation scheme corresponding to a modulation scheme on the transmitter side.

The error correction decoder according to the aforementioned first embodiment is incorporated into the decoder 324. The decoder 324 performs decoding process including error correction decoding on the demodulated data from the demodulator 323 to reconstruct the received data.

As explained above, in the receiver according to the third embodiment, the error correction decoder according to the aforementioned first embodiment is incorporated into the decoder. Thus, according to the receiver according to the present embodiment, an excellent ability of error correction for the received data can be achieved. The transmitter-receiver may be configured by combining the elements shown in FIG. 9 and other necessary elements for a transmitter that are not shown in FIG. 9.

For example, it is possible to provide a program that realizes the processing of each of the above-described embodiments by storing the program in a computer-readable storage medium. A storage medium may be a magnetic disk, an optical disc (such as CD-ROM, CD-R, DVD, etc.), a magneto-optical disc (MO, etc.) or a semiconductor memory, as long as it can store a program and is computer-readable.

Also, the program that realizes the processing of each of the above-described embodiments may be stored on a computer (server) connected to network such as the Internet and may be downloaded by a computer (client) via network.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An error correction decoder which carries out iterative decoding for data coded using an irregular LDPC code, comprising:
a row processing unit configured to generate each extrinsic value from each check node to each variable node;
a parity check unit configured to generate a temporary estimated word based on the extrinsic values, to perform parity checks on the temporary estimated word, and to determine the temporary estimated word as a code word when all check nodes satisfy the parity check; and
a likelihood control unit configured to carry out weighting using first extrinsic value weights when a first condition including a condition that the code word cannot be obtained even when number of times the iterative decoding has been carried out is greater than a first iterative times, in order to increase absolute value of the extrinsic value from the check node not satisfying the parity check to the variable node, wherein the first extrinsic value weights are equal to each other or become larger in descending order of column weights of the variable nodes, and a maximum of the first extrinsic value weights is not equal to a minimum of the first extrinsic value weights.

2. The decoder according to claim 1, wherein,
the minimum of the first extrinsic value weights is greater than 1,
when the first condition is satisfied, the likelihood control unit multiplies, by the first extrinsic value weight, the extrinsic value from the check node not satisfying the parity check to the variable node.

3. The decoder according to claim 1, wherein, the first condition includes a condition that a code word cannot be obtained even when the number of times the iterative decoding has been carried out is greater than the first iterative times and total number of check nodes not satisfying the parity check is less than or equal to a first maximum.

4. The decoder according to claim 1, wherein, the likelihood control unit carried out weighting using second extrinsic value weights when the first condition is satisfied, in order to decrease absolute value of the extrinsic value from the check node satisfying the parity check to the variable node connected to the check node not satisfying the parity check, wherein the second extrinsic value weights are equal to each other or become less in descending order of the column weights of the variable nodes, and a maximum of the second extrinsic value weights is not equal to a minimum of the second extrinsic value weights.

5. The decoder according to claim 4, wherein,
the maximum of the second extrinsic value weights is less than 1,
when the first condition is satisfied, the likelihood control unit multiplies, by the second extrinsic value weight, the extrinsic value from the check node satisfying the parity check to the variable node connected to the check node not satisfying the parity check.

6. The decoder according to claim 4, wherein,
the maximum of the second extrinsic value weights is less than or equal to zero,
when the first condition is satisfied, the likelihood control unit adds the second extrinsic value weight to the absolute value of the extrinsic value from the check node satisfying the parity check to the variable node connected to the check node not satisfying the parity check.

7. The decoder according to claim 1, wherein,
the minimum of the first extrinsic value weights is greater than or equal to zero,
when the first condition is satisfied, the likelihood control unit adds the first extrinsic value weight to the absolute value of the extrinsic value from the check node not satisfying the parity check to the variable node.

8. A memory controller, comprising:
a reading unit configured to receive data coded using the irregular LDPC code from a nonvolatile memory; and
the error correction decoder according to claim 1.

9. A receiver, comprising:
a demodulation unit configured to demodulate a received signal and obtain data coded using the irregular LDPC code; and
the error correction decoder according to claim 1.
